(19) United States
(12) Patent Application Publication
(10) Pub. No.: US 2010/0314610 A1
(43) Pub. Date: Dec. 16, 2010

(54) HEMT WITH IMPROVED QUANTUM CONFINEMENT OF ELECTRONS

(76) Inventors: Samson Mil'shtein, Chelmsford, MA (US); Amey V. Churi, Lowell, MA (US); Brian J. Rizzi, Auburn, NH (US); Peter N. Ersland, Littleton, MA (US)

Correspondence Address: WOLF GREENFIELD & SACKS, P.C., 600 ATLANTIC AVENUE, BOSTON, MA, 02210-2206, US

(21) Appl. No.: 12/757,252

(22) Filed: Apr. 9, 2010

Related U.S. Application Data
(60) Provisional application No. 61/168,456, filed on Apr. 10, 2009.

(51) Int. Cl. H01L 29/778

(52) U.S. Cl. 257/24; 257/194; 257/E29.248

(57) ABSTRACT

A HEMT with improved electron confinement is formed by removing semiconductor cap material between the channel and the source and drain regions. The source and drain regions can be isolated from the gate region by an insulating layer. Significant noise reduction can be achieved as a result of these techniques. Also, removing the semiconductor cap material can provide an increased breakdown voltage for the transistor.

### RELATED APPLICATIONS

This application claims priority under 35 U.S.C. § 119(e) to U.S. Provisional Application Ser. No. 61/168,456, entitled “HEMT WITH IMPROVED QUANTUM CONFINEMENT OF ELECTRONS,” filed Apr. 10, 2009, which is hereby incorporated by reference herein in its entirety.

### DISCUSSION OF RELATED ART

The Pseudomorphic High Electron Mobility Transistor (p-HEMT) is widely used in microwave applications. The advantage of high electron mobility in the channel of this transistor over other field effect devices can be described based on the quantum behavior of carriers. Energy levels positioned closed to the bottom of the quantum well of HEMTs provide for easy electron transition from localized donor levels. As a consequence, large electron sheet density can be achieved even at low temperatures.

The properties of the 2-D electron gas have been modeled and studied both theoretically and experimentally dating back to the early years of HEMT development. Measurements at low temperatures established the presence of traps resulting in persistent photoconductivity. A variety of deep defect levels were identified in HEMTs by DLTS measurements. Another low temperature study revealed the existence of steps on I-V (current-voltage) characteristics. The appearance of these steps was attributed to the activity of a large number of defects which were trapping free electrons, thus causing so-called current collapse. This explanation assumes the presence of an extremely large density of identical traps and that all of the traps have the same orientation with respect to the electrical field induced by the gate bias. For a variable electric field under the gate, the trapping cross-section of all defects was expected to increase, causing massive current collapse. However, this theory does not explain how such trap activities can be simultaneous and coherent on a large scale.

Applicants have proposed an alternative explanation for the experimental measurements at low temperatures performed on p-HEMTs. We believe the appearance of the steps on the current-voltage characteristics is a result of the transitions of electrons caused by the electrons being heated by the electric field, which changes the effective density of carriers. Previous HEMTs have not exhibited quantum confinement, which can be checked by low temperature measurements. Another problem with commercial pHEMTs is that they manifest no quantization even at low temperatures. Lack of electron quantization can result in the generation of noise.

### SUMMARY

Some embodiments relate to a high electron mobility transistor that includes a channel region and a doped semiconductor region formed above the channel region. The transistor also includes a gate that forms a Schottky contact with the doped semiconductor region, a source region and a drain region. The transistor also includes at least one insulating layer that isolates the source region from the doped semiconductor region and the drain region from the semiconductor region.

Some embodiments relate to a high electron mobility transistor that includes a channel region, a gate, and a drain region separated from the channel region by no more than 100 angstroms. The transistor also includes a source region separated from the channel region by no more than 100 angstroms. Portions of the drain region and the source region nearest the channel region are formed far enough from the gate such that carriers flow through the entire length of the channel region between the source region and the drain region.

### BRIEF DESCRIPTION OF DRAWINGS

As is conventional in the representation of semiconductor devices, the drawings are not necessarily drawn to scale for purposes of illustration.

FIG. 1 shows a conventional HEMT structure.

FIG. 2 shows an embodiment of a HEMT structure with improved quantum confinement.

FIG. 3 shows I-V characteristics of the transistors of FIGS. 1 and 2.

### DETAILED DESCRIPTION

The Applicants have appreciated that the conventional HEMT structure does not provide a high degree of electron confinement. This lack of confinement is caused at least partially by the use of highly doped semiconductor cap layers near the transistor's channel. The lack of quantum confinement can allow electrons to escape from the channel region, thus destroying the two-dimensional electron gas and its interaction with the set of the prescribed discrete energy levels in the channel region, which in turn leads to greater noise in the transistor operation. The Applicants have improved electron confinement by removing semiconductor cap material between the channel and the source and drain regions. The source and drain regions can be isolated from the gate region by an insulating layer. Significant noise reduction can be achieved as a result of these techniques. Also, removing the semiconductor cap material can provide an increased breakdown voltage for the transistor.

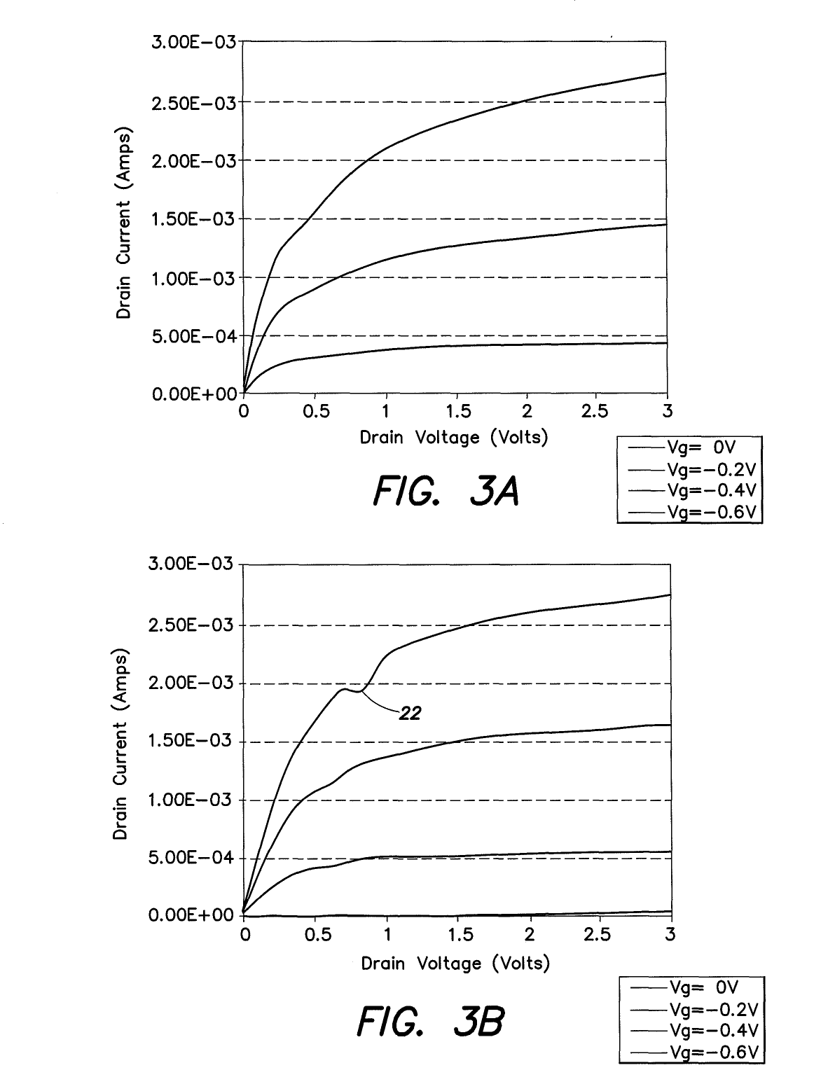

FIG. 1 shows the conventional structure of a HEMT 1. As shown in FIG. 1, the conventional HEMT 1 has an InGaAs channel 2 of intrinsic semiconductor material approximately 150 \dot{A} thick. Thin delta doped layers 3, 4 of about 15-20 \dot{A} thick are formed on either side of the InGaAs channel 2 to supply carriers to the channel region. An AlGaAs to doped layer 4 is formed above the channel's upper delta doped region 3. A control gate 5 forms a Schottky contact with the AlGaAs layer 4. Heavily doped GaAs cap layers 6, 7, having a thickness of more than a thousand angstroms, are formed on the AlGaAs doped layer 4. The GaAs cap layers 6, 7 also supply carriers to the channel region. Source and drain contacts 8, 9, are formed on the GaAs cap layers. The results of modeling the I-V characteristics of a commercial single gate p-HEMT at low temperatures is shown in FIG. 3a. FIG. 3a shows that the device does not exhibit any abrupt steps in the I-V characteristics that could be attributed to quantum effects. The weak electron confinement is believed to have prevented the manifestation of electron quantum behavior.

The Applicants have appreciated that the highly doped GaAs cap layers 6, 7 can reduce the quantum confinement in the device channel region. As shown in FIG. 1, the step-like shape of the GaAs cap layers 6, 7 can be close to the gate 5. As a result, electrons avoid the channel and instead flow in the GaAs cap layers 6, 7 until they are relatively close to the gate. This prevents electron confinement in the channel region.

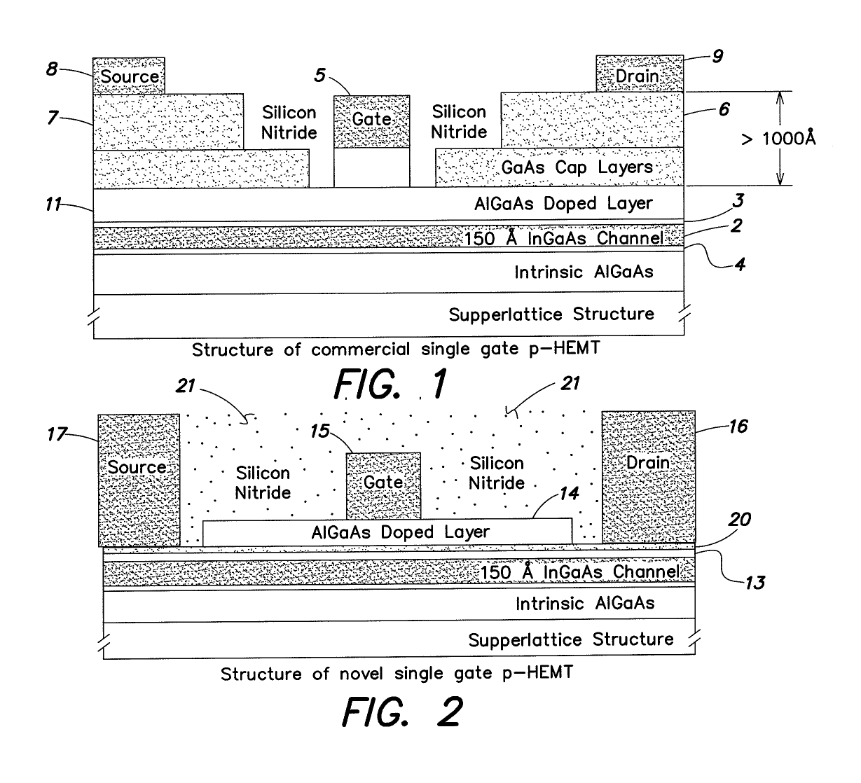

FIG. 2 shows an embodiment of a HEMT transistor 10 in which a large portion of the GaAs cap layers have been removed, according to some embodiments. For example, the GaAs cap layers 16, 17 can be removed to within about 100 \dot{A} of the channel. The AlGaAs doped layer 14 may be removed from the region between the channel and the source and drain regions. The source and drain regions 16, 17 may be regions of GaAs formed on an etch-stop layer 20 about 100 \dot{A} from the channel, although, in some embodiments, the source and drain regions may be formed closer to the channel. For example, the source and/or drain contacts may reach the delta doping 13 on the upper portion of the channel region. As shown in FIG. 2, the AlGaAs doped layer 14 may be formed under the gate and not under the source or drain regions 16, 17. The source and/or drain regions 16, 17 can be isolated from the doped AlGaAs layer 14 by an insulating layer 21 made of insulating material such as Si₃N₄. Unlike a GaAs cap layer, the portion of the source and drain regions nearest the channel are a significant distance from the gate, causing electrons to flow within the channel region for the entire length of the channel between the source and the drain. Such a transistor structure can provide improved electron confinement in the channel region.

A single transistor gate can be used or multiple gates can be used, such as two or more gates. If one gate is used, the gate can be positioned in the center of the channel, shifted toward the source, or positioned in another suitable location. Flexible control over the flow of quantized electrons can be provided by using two or more gates, according to design criteria.

FIG. 3b shows the modeled I-V characteristics of the p-HEMT of FIG. 2 at a low temperature of about 150° K. The modeling shows the signature of stepping (quantization) 22 in the I-V curves, demonstrating the presence of quantum confinement.

Having thus described an illustrative embodiment of the invention, it should be apparent to those skilled in the art that the foregoing is merely illustrative and not limiting, having been presented by way of example only. Numerous modifications and other illustrative embodiments may be contemplated by those of ordinary skill in the art and are believed to fall within the scope of the invention. For example, although a HEMT transistor may be formed using materials such as AlGaAs and InGaAs as described herein, other suitable materials may be used, as the techniques described herein are not limited to particular materials. For example, other types of III-V semiconductor materials may be used.

What is claimed is:

1. A high electron mobility transistor, comprising:
a channel region;
a doped semiconductor region formed above the channel region;
a gate that forms a Schottky contact with the doped semiconductor region;
a source region;
a drain region; and
at least one insulating layer that isolates the source region from the doped semiconductor region and the drain region from the semiconductor region.

2. A high electron mobility transistor, comprising:
a channel region;
a gate;
a drain region separated from the channel region by no more than 100 angstroms; and
a source region separated from the channel region by no more than 100 angstroms;
wherein the portions of the drain region and the source region nearest the channel region are formed far enough from the gate such that carriers flow through the entire length of the channel region between the source region and the drain region.

3. The high electron mobility transistor of claim 2, wherein no semiconductor cap layer is formed between the source or drain contacts and the channel.

4. The high electron mobility transistor of claim 2, wherein the transistor quantizes electron energy levels in the channel region due to improved electron confinement in the channel region.

5. The high electron mobility transistor of claim 4, wherein the quantization of electron energy levels enables improved noise performance.

6. The high electron mobility transistor of claim 4, wherein the quantization of electron energy levels provides higher and more uniform transconductance.
